(19) United States
(12) Patent Application Publication
(10) Pub. No.: US 2010/0085696 A1
(43) Pub. Date: Apr. 8, 2010

(54) DISPLAY APPARATUS

(75) Inventors: Jong-Seong KIM, Seoul (KR); Min-Ho Yoon, Seoul (KR); Seung-Jin Baek, Seoul (KR)

Correspondence Address: H.C. PARK & ASSOCIATES, PLC, 8500 LEESBURG PIKE, SUITE 7500, VIENNA, VA, 22182, US

(73) Assignee: Samsung Electronics Co., Ltd., Suwon-si (KR)

(21) Appl. No.: 12/402,041

(22) Filed: Mar. 11, 2009

(30) Foreign Application Priority Data
Oct. 7, 2008 (KR) 2008-98214

(51) Int. Cl. H05K 1/03

(52) U.S. Cl. 361/679.21

(57) ABSTRACT

The present invention discloses a display apparatus including a display panel that includes a first flexible substrate including a plurality of pixels and a second flexible substrate coupled with the first flexible substrate, the display panel to display an image, and at least one driver integrated circuit (IC) arranged on a display panel, the driver IC to apply a driving signal to the pixels. The driver IC has a length less than a curvature radius of the first flexible substrate, the curvature radius based on the first flexible substrate to which a pressure of 1 Gpa is applied.

### CROSS REFERENCE TO RELATED APPLICATION

This application claims priority from and the benefit of Korean Patent Application No. 2008-98214, filed on Oct. 7, 2008, which is hereby incorporated by reference for all purposes as if fully set forth herein.

### BACKGROUND OF THE INVENTION

1. Field of the Invention

The present invention relates to a flexible display apparatus.

2. Discussion of the Background

A display apparatus that displays images using light supplied from a separate light source requires an optical shutter disposed between two substrates thereof. The optical shutter controls amount of light passing through one substrate and then exiting from another substrate. As one type of display apparatus including the optical shutter, a liquid crystal display (LCD) includes a liquid crystal layer that serves as the optical shutter.

A plastic LCD includes a plastic substrate instead of a glass substrate, so that the plastic LCD may include a flexible LCD panel having greater flexibility than that of a conventional LCD panel.

The LCD typically includes a gate driver and a data driver in order to drive the LCD panel. The gate and data drivers are mounted on the LCD panel in an integrated chip (IC) form. Since the driver IC is formed from a silicon wafer, the driver IC has bending strength less than that of the plastic substrate. Accordingly, the driver IC mounted on the flexible LCD panel may be easily damaged due to bending of the flexible LCD panel.

### SUMMARY OF THE INVENTION

The present invention provides a display apparatus including a flexible substrate that may prevent a driver IC mounted thereon from being damaged.

The present invention also provides a display apparatus including a driver IC having a length smaller than a curvature radius of a first flexible substrate, so the driver IC may be prevented from being damaged by bending the flexible display panel.

Additional features of the invention will be set forth in the description which follows, and in part will be apparent from the description, or may be learned by practice of the invention.

The present invention discloses a display apparatus including a display panel including a first flexible substrate including a plurality of pixels, a second flexible substrate, and at least one driver IC. The second flexible substrate is coupled with the first flexible substrate, the display panel to display an image. The driver IC is arranged on the display panel, the driver IC to apply a driving signal to the pixels. The driver IC has a length less than a curvature radius of the first flexible substrate, the curvature radius based on the first flexible substrate to which a pressure of 1 Gpa is applied.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a plan view showing a display apparatus according to an exemplary embodiment of the present invention.

FIG. 2 is a view showing a curvature radius of a first flexible substrate of FIG. 1.

FIG. 3A, FIG. 3B, and FIG. 3C are views showing a method of measuring bending strength of a driver IC with respect to a length of the driver IC using a tri-axial bending test apparatus.

FIG. 4A, FIG. 4B, and FIG. 4C are graphs showing the bending strength of the driver IC with respect to the length of the driver IC, which is measured by the tri-axial bending test apparatus.

FIG. 5 is a sectional view showing a conventional first flexible substrate on which a driver IC, which has a length of 10 mm or greater, is mounted.

FIG. 6 is a sectional view showing a first flexible substrate on which a plurality of driver ICs, which has a length of 6 mm or less, is mounted according to the present invention.

### DETAILED DESCRIPTION OF THE ILLUSTRATED EMBODIMENTS

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these exemplary embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

Hereinafter, exemplary embodiments of the present invention will be explained in detail with reference to the accompanying drawings.

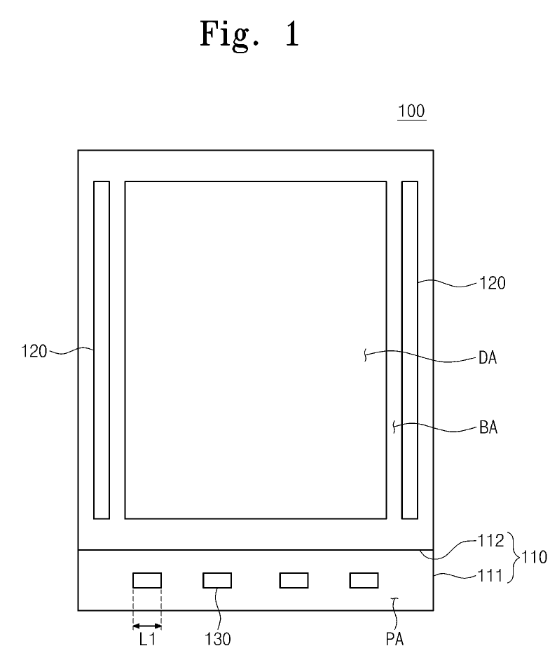

FIG. 1 is a plan view showing a display apparatus according to an exemplary embodiment of the present invention.

Referring to FIG. 1, a display apparatus 100 includes a display panel 110 to display images.

The display panel 110 includes a first flexible substrate 111, a second flexible substrate 112 facing the first flexible substrate 111, and a liquid crystal layer (not shown) disposed between the first and second flexible substrates 111 and 112.

In the present exemplary embodiment, the first and second flexible substrates 111 and 112 may include a plastic material, such as polyethylene terephthalate (PET), poly carbonate (PC), polyethylene naphthalate (PEN), polyether sulfone (PES), fiber reinforced plastic (FRP), etc., so the first and second flexible substrates 111 and 112 may bend.

The first flexible substrate 111 includes a display area DA, in which images are displayed, a black matrix area BA, which surrounds the display area DA, and a peripheral area PA, which is adjacent to one side of the black matrix area BA.

Although not shown in the drawings, the first flexible substrate 111 includes a plurality of pixels arranged in the display area DA in a matrix configuration. In detail, a plurality of gate lines and a plurality of data lines are arranged in the display area DA. The gate lines and the data lines define a plurality of pixel areas in the display area DA. The pixels are arranged in the pixel areas, respectively, and each pixel includes a thin film transistor and a liquid crystal capacitor.

The second flexible substrate 112 includes a color filter and a common electrode. The color filter includes red, green, and blue color filters. The common electrode is formed on an entire surface of the second flexible substrate 112 and faces the pixel electrode to form the liquid crystal capacitor.

The display apparatus 100 further includes a gate driver 120 and a data driver 130. As an example of the present invention, in FIG. 1, the gate driver 120 includes amorphous silicon transistors and is directly formed on the first flexible substrate 111 through a thin film process. In the present exemplary embodiment, the gate driver 120 includes two shift registers and is arranged in the black matrix area BA of the display panel 100. The two shift registers are electrically connected to both ends of the gate lines, respectively. Thus, the gate driver 120 sequentially applies a gate signal to the gate lines GL1˜GLn.

In FIG. 1, a structure that the gate driver 120 includes two shift registers electrically connected to both ends of the gate lines, respectively, has been shown, but the gate driver 120 may include only one shift register electrically connected to one end of the gate lines.

The data driver 130 includes a plurality of chips (hereinafter, referred to as driver ICs), and the driver ICs are arranged in the peripheral area PA while being spaced apart from each other. The driver ICs 130 are electrically connected to the data lines to provide a data signal to the data lines.

Since the driver ICs 130 are formed from a silicon wafer, the driver ICs 130 have a bending strength less than that of the first flexible substrate 111 including the plastic material. In order to prevent damage to the driver ICs 130 due to bending the first flexible substrate 111, each driver IC 130 has a length less than a curvature radius of the first flexible substrate 111 when a pressure of 1 Gpa is applied to the first flexible substrate 111.

Although not shown in FIG. 1, the gate driver 120 may have an IC form and may be mounted on the first flexible substrate 111. In this case, the IC for the gate driver 120 may have a length less than the curvature radius of the first flexible substrate 111 when the pressure of 1 Gpa is applied to the first flexible substrate 111.

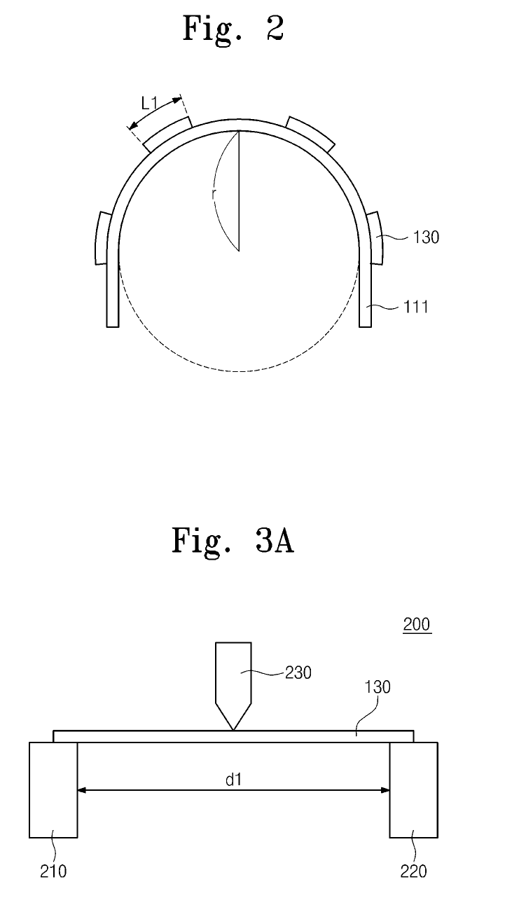

FIG. 2 is a view showing a curvature radius of a first flexible substrate 111 of FIG. 1.

Referring to FIG. 2, the curvature radius (r) of the first flexible substrate 111 satisfies the following Equation.

$$r = \frac{{t}^{2} Ms}{6 f} \qquad Equation$$

In the above Equation, t denotes a thickness of the first flexible substrate 111, Ms denotes a modulus, and f denotes a pressure applied to the first flexible substrate 111.

According to the Equation, when the pressure of 1 Gpa is applied to the first flexible substrate 111 after the thickness t of the first flexible substrate 111 and the modulus of elasticity of the first flexible substrate 111 Ms are decided, the curvature radius r may be calculated. In the present exemplary embodiment, the thickness t of the first flexible substrate 111 has a range of about 20 μm to about 200 μm.

The driver IC 130 has a length L1 less than the curvature radius r calculated by the above Equation. Thus, the driver IC 130 may be prevented from being damaged even though the display panel 110 is bent.

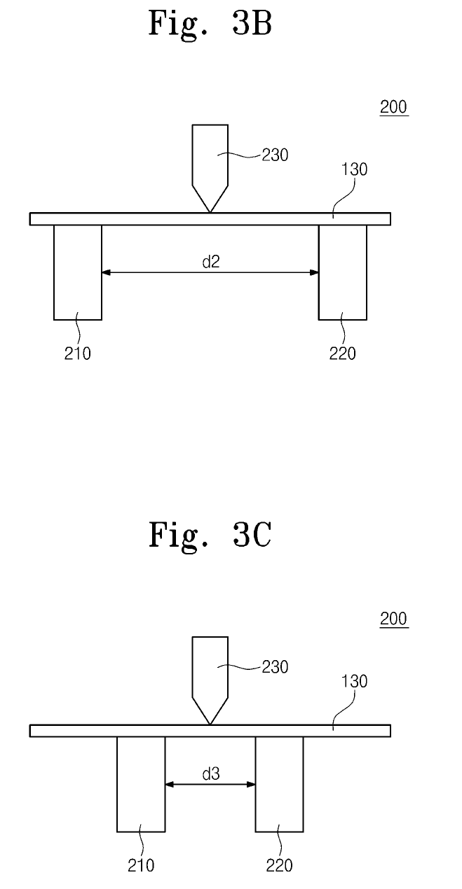

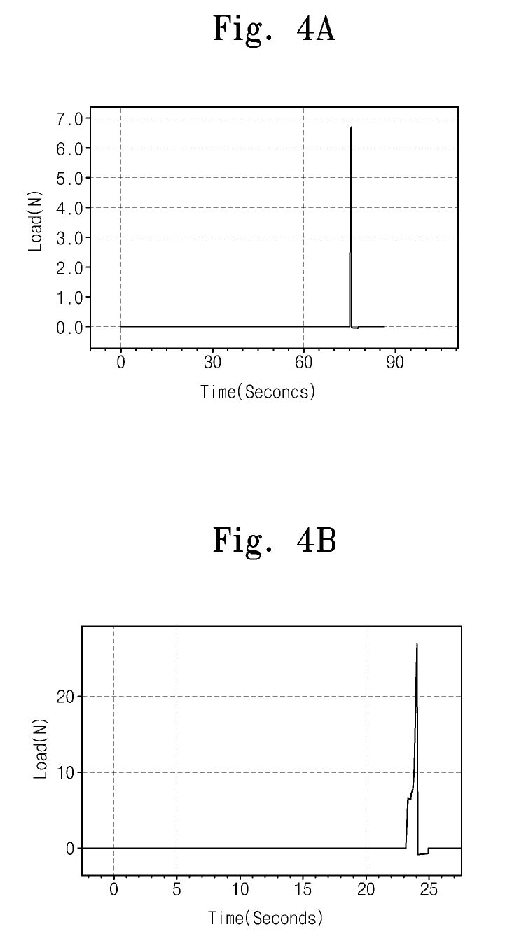

FIG. 3A, FIG. 3B, and FIG. 3C are views showing a method of measuring bending strength of a driver IC with respect to a length of the driver IC using a tri-axial bending test apparatus, and FIG. 4A, FIG. 4B, and FIG. 4C are graphs showing the bending strength of the driver IC with respect to the length of the driver IC, which is measured by the tri-axial bending test apparatus.

Referring to FIG. 3A, the tri-axial bending test apparatus 200 includes first and second supporting shafts 210 and 220 that are spaced apart from each other, and a punch 230 positioned at a center portion between the first and second supporting shafts 210 and 220. The punch 230 may be moved upward and downward.

The first and second supporting shafts 210 and 220 are spaced apart from each other by a distance dl of about 10 mm, and the driver IC 130 is disposed on the first and second supporting shafts 210 and 220 to measure the bending strength of the driver IC 130. In the present exemplary embodiment, the driver IC 130 for the bending strength test has a thickness of about 0.514 mm and a width of about 1.7 mm.

When a predetermined load is applied to the driver IC 130 by the punch 230, the driver IC 130 is gradually deformed and then broken. The load applied to the driver IC at a time point where the driver IC is broken is measured as the bending strength of the driver IC.

As shown in FIG. 3A and FIG. 4A, with the distance dl between the first and second supporting shafts 210 and 220 being set to 10 mm, the driver IC 130 is broken when a load of about 6.7 N is applied to the driver IC 130. Accordingly, when the driver IC 130 has the length of about 10 mm, the bending strength of the driver IC 130 is about 6.7 N.

As shown in FIG. 3B and FIG. 4B, when the distance d2 between the first and second supporting shafts 210 and 220 is reduced to about 6 mm, the driver IC 130 may bear a load of about 28 N. Consequently, when the driver IC 130 has the length of about 6 mm, the bending strength of the driver IC 130 is about 28 N.

In addition, as shown in FIG. 3C and FIG. 4C, when the distance d3 between the first and second supporting shafts 210 and 220 is reduced to about 2 mm, the driver IC 130 may bear a load of about 100 N or more.

As shown by the above test results, since the load that the driver IC 130 may bear without breaking increases as the length of the driver IC 130 decreases, the driver IC 130 may be prevented from being damaged by bending the first flexible substrate 111 when the length of the driver IC 130 is reduced.

In the present exemplary embodiment, the driver IC 130 has the length of about 6 mm or less so that the driver IC 130 has the bending strength of about 28 N. In addition, in order to increase the bending strength of the driver IC 130 over 100 N, the length of the driver IC 130 may be set to about 2 mm or less.

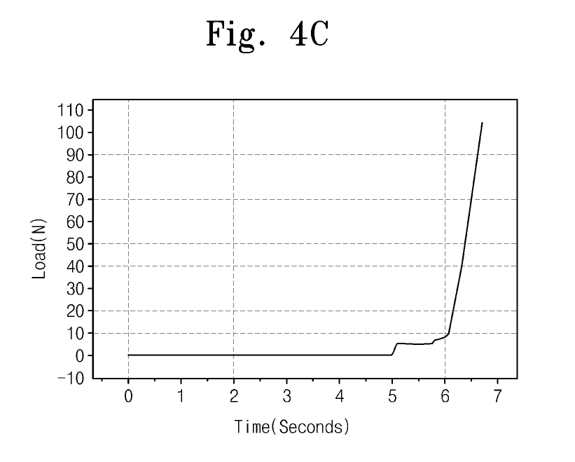

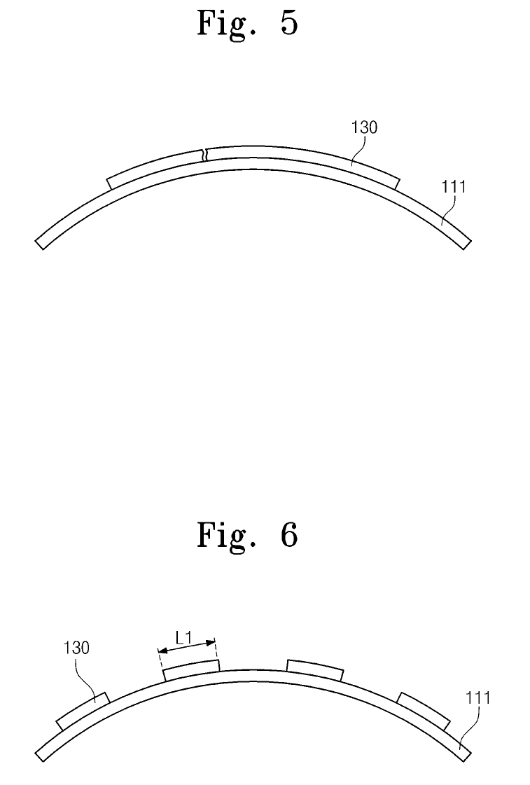

FIG. 5 is a sectional view showing a conventional first flexible substrate on which a driver IC, which has a length of 10 mm or greater, is mounted, and FIG. 6 is a sectional view showing a first flexible substrate on which a plurality of driver ICs, which have a length of 6 mm or less, is mounted according to the present invention.

Referring to FIG. 5, when the first flexible substrate 111 is bent after the driver IC 130 having the length of about 10 mm or greater is mounted on the first flexible substrate 111, the driver IC 130 may be easily broken since a load, applied to the driver IC 130 when the flexible substrate 111 is bent, is concentrated in the same region, e.g. a center portion of the driver IC 130.

However, when the length L1 of the driver IC 130 is set to about 6 mm or less as shown in FIG. 6, the load that the driver IC 130 may bear increases, thereby preventing the damage of the driver IC 130.

In FIG. 1, FIG. 2, FIG. 3A, FIG. 3B, FIG. 3C, FIG. 4A, FIG. 4B, FIG. 4C, FIG. 5, and FIG. 6, the LCD has been described as an exemplary embodiment of the present invention, but it is applicable to all display apparatuses including the flexible substrate. That is, in the display apparatus employing the flexible substrate, such as an organic light emitting display apparatus, electrophoretic display apparatus, or the like, if the driver IC mounted on the flexible substrate is set to have the length less than the curvature radius of the flexible substrate to which the pressure of 1 Gpa is applied, the driver IC may be prevented from being damaged by bending the flexible substrate.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A display apparatus, comprising:
a display panel comprising a first flexible substrate comprising a plurality of pixels and a second flexible substrate coupled with the first flexible substrate, the display panel to display an image; and
at least one driver integrated circuit (IC) arranged on the display panel, the driver IC to apply a driving signal to the pixels,
wherein the driver IC has a length less than a curvature radius of the first flexible substrate, the curvature radius based on the first flexible substrate to which a pressure of 1 Gpa is applied.

2. The display apparatus of claim 1, wherein the first flexible substrate and the second flexible substrate each comprise a plastic material and the driver IC comprises a silicon wafer.

3. The display apparatus of claim 2, wherein the plastic material comprises polyethylene terephthalate (PET), poly carbonate (PC), polyethylene naphthalate (PEN), polyether sulfone (PES), and fiber reinforced plastic (FRP).

4. The display apparatus of claim 1, wherein the curvature radius of the first flexible substrate satisfies an equation of
$$r = \frac{{t}^{2} Ms}{6 f} ,$$
where r denotes the curvature radius, t denotes a thickness of the first flexible substrate, Ms denotes a modulus of elasticity of the first flexible substrate, and f denotes a pressure applied to the first flexible substrate.

5. The display apparatus of claim 4, wherein the length of the driver IC is 6 mm or less.

6. The display apparatus of claim 5, wherein the length of the driver IC is 2 mm or less.

7. The display apparatus of claim 5, wherein the display panel comprises:
a vertical side that extends along a first direction; and
a horizontal side that extends along a second direction, the horizontal side shorter than the vertical side,
wherein the length of the driver IC is measured along the second direction.

8. The display apparatus of claim 4, wherein the thickness of the first flexible substrate has a range of about 20 μm to about 200 μm.

9. The display apparatus of claim 1, wherein the driver IC is spaced apart from an adjacent driver IC.
